(19) United States
(12) Patent Application Publication
(10) Pub. No.: US 2026/0016179 A1
(43) Pub. Date: Jan. 15, 2026

(54) AUTOMATIC DETECTION OF APPLIANCE DEVIATION FROM NORMAL OPERATION

(71) Applicant: Ademco Inc., Golden Valley, MN (US)

(72) Inventors: David G. Quam, Maple Grove, MN (US); Adam C.H. Myre, Minnetonka, MN (US)

(73) Assignee: Ademco Inc., Golden Valley, MN (US)

(21) Appl. No.: 18/875,929

(22) PCT Filed: Jun. 23, 2023
(86) PCT No.: PCT/US2023/026032

§ 371 Date: Dec. 17, 2024

Related U.S. Application Data
(60) Provisional application No. 63/355,737, filed on Jun. 27, 2022.

(51) Int. Cl. F24F 11/49; G01R 15/18; G01R 19/00

(52) U.S. Cl. CPC F24F 11/49; G01R 15/18; G01R 19/0092

(57) ABSTRACT

Techniques herein measure characteristics of outflow air in an HVAC system and determining whether the measurements suggest an impending failure of one or more components of the HVAC system. A normal operation pattern may be determined based on a statistically significant set of characteristic measurements. A present measurement that deviates from the normal operation pattern may suggest the impending failure. A user may be notified of the deviation. Additional appliance information may be preserved for the time period that includes when the present measurement was taken to provide context for a person repairing the appliance. In some embodiments, the system for implementing one or more of the techniques described herein is made up of only a current transformer for detecting a call from the thermostat to the appliance or monitoring charge statuses on the thermostat and an outflow air sensor.

### TECHNICAL FIELD

The present disclosure relates generally to home automation devices, including heating, ventilation, and/or air conditioning (HVAC) controllers.

### BACKGROUND

HVAC appliances rarely fail without any warning. Often a sub-system (e.g., an ignitor, a pressure switch, a limit sensor, etc.) will have intermittent issues that will cause the system to go into a re-try loop. If these intermittent issues are infrequent and the system recovers, occupants of that space may not be able to tell that their HVAC system is starting to fail if their comfort level is still being met. These intermittent issues often precede a full system shutdown and/or lockout that occupants will certainly notice when their living space is not being heated or cooled to meet their comfort needs. This is when most homeowners will call a professional HVAC technician to diagnose and fix this issue.

Setting up temperature alerts (e.g., measured at the thermostat) to detect a system lockout is a valid way to know something is wrong. However, this is often too late and well after the intermittent warning signs have passed.

### SUMMARY

In general, the disclosure is directed to techniques for providing methods for analyzing temperatures in air ducts when heating and/or cooling terminals are powered. For instance, when a thermostat calls for an appliance, such as a furnace, an air conditioner, or a humidifier, to modify air flowing through the appliance and, ultimately, expelled from an outflow duct of the HVAC system, a measurement of a characteristic of that air may be taken. After taking multiple measurements, a normal operation pattern may be created to define how the HVAC system, when working properly, will alter the air flowing through the appliance. As additional measurements are taken during additional thermostat calls, the current measurements can be compared to the normal operation pattern to determine whether the current measurements of the characteristic deviate from the normal operation pattern. If a deviation is detected, the system may notify one or more of the user and a remote server such that the HVAC system can be properly maintained and/or repaired.

Rather than requiring sensors in both an inflow duct and an outflow duct with additional operations to calculate differences between the inflow duct measurement and the outflow duct measurement, the techniques described herein may only take measurements in the outflow duct. By comparing the measurements in the outflow duct to a normal operation pattern, the overall calculations are simplified and decreased, improving the operation of the system performing these calculations. Additionally, by only taking measurements of the outflow duct, the installation is simplified. Trigger thresholds are more sensitive when based on one measurement rather than a combination of measurements, resulting in quicker determinations that measurements are to be taken. It is also easier to retrofit existing systems with sensors in a single location rather than in multiple locations.

One embodiment includes a method comprising providing an HVAC system that includes an appliance, an inflow duct, an outflow duct, and a thermostat. The method further comprises taking a measurement of a characteristic of outflowing air in the outflow duct each time the thermostat calls for the appliance to modify air flowing through the appliance. The method also comprises establishing a normal operation pattern based on the measurements. The method further comprises identifying a deviation when a present measurement of the characteristic of outflowing air deviates from the normal operation pattern. The method also comprises notifying a user of the deviation.

In a further embodiment of the method, identifying the deviation comprises comparing the present measurement of the characteristic to the normal operation pattern, determining whether the present measurement is greater than a threshold deviation away from the normal operation pattern, and in response to determining that the present measurement is greater than the threshold deviation away from the normal operation pattern, classifying the present measurement as the deviation.

In a further embodiment of the method, the method further includes receiving, by the thermostat, an indication of user input to modify the air flowing through the appliance and initiating, by the thermostat, a first call for the appliance to modify the air flowing through the appliance.

In one such example of the further embodiment, the method further includes providing an air sensor in the outflow duct.

In another such example of the further embodiment, taking the measurement of the characteristic comprises measuring, by the air sensor, the characteristic of the outflowing air and sending, by the air sensor, the characteristic to one or more processors that establish the normal operation pattern.

In another such example of the further embodiment, the air sensor comprises one or more of a temperature sensor, a pressure sensor, a humidity sensor, a particulate sensor, an acoustic sensor, and a gas sensor.

In a further embodiment of the method, the characteristic comprises one or more of a temperature of the outflowing air in the outflow duct, a blowing pressure of the outflowing air in the outflow duct, a humidity of the outflowing air in the outflow duct, a solid particle concentration of the outflowing air in the outflow duct, a noise characteristic of the outflowing air in the outflow duct, and a gas particle concentration of the outflowing air in the outflow duct.

In a further embodiment of the method, the method further includes, in response to identifying the deviation, notifying a remote server of the deviation.

In a further embodiment of the method, the method further includes preserving additional appliance operation information for a time period that includes when the present measurement was taken.

In one such example of the further embodiment, the method further includes providing one or more additional sensors in the appliance and, in response to the thermostat calling for the appliance to modify the air flowing through the appliance, activating the one or more additional sensors to measure the additional appliance operation information for at least the time period.

In another such example of the further embodiment, the additional appliance operation information comprises one or more of motor activation data, temperature control data, gas valve data, rectifier confirmation data, blower data, and moisture data.

The example could further include notifying a remote server of the additional appliance operation information.

In a further embodiment of the method, the appliance comprises one or more of a furnace, an air conditioner, and a humidifier.

In a further embodiment of the method, the method further includes determining local environmental factors, wherein identifying the deviation comprises identifying the deviation based on the present measurement of the characteristic and the local environmental factors.

In one such example of the further embodiment, the local environmental factors comprise one or more of indoor temperature, indoor humidity, outdoor temperature, outdoor humidity, and a local weather reading.

Another embodiment includes a system comprising an HVAC system that includes an appliance, an inflow duct, an outflow duct, and a thermostat. The HVAC system further includes a first sensor provided in the outflow duct, the first sensor being configured to take a measurement of a characteristic of outflowing air in the outflow duct each time the thermostat calls for the appliance to modify air flowing through the appliance. The HVAC system further includes one or more processors configured to receive the measurements of the characteristic of the outflowing air in the outflow duct. The one or more processors are further configured to establish a normal operation pattern based on the measurements. The one or more processors are also configured to receive a present measurement of the characteristic of the outflowing air. The one or more processors are further configured to identify a deviation when the present measurement of the characteristic of outflowing air deviates from the normal operation pattern. In response to identifying the deviation, the one or more processors are further configured to preserve additional appliance operation information for a time period that includes when the present measurement was taken.

In a further embodiment of the system, the HVAC system further includes a second sensor provided in the appliance. The second sensor is configured to, in response to the thermostat calling for the appliance to modify the air flowing through the appliance, measure the additional appliance operation information for at least the time period. In some such embodiments, the one or more processors may be configured to query the second sensor for the additional appliance operation information and receive the additional appliance operation information from the second sensor.

In a further embodiment of the system, when the one or more processors identifies a deviation, the one or more processors is configured to notify a user of the deviation.

In a further embodiment of the system, the one or more processors are further configured to notify a remote server of the additional appliance operation information.

In a further embodiment of the system, the system further comprises one or more indoor environmental sensors and one or more outdoor environmental sensors.

In one such example of the further embodiment, the one or more processors are further configured to receive indoor local environmental information from the one or more indoor environmental sensors, receive outdoor local environmental information from the one or more outdoor environmental sensors, and identify the deviation based on the present measurement of the characteristic, the indoor local environmental information, and the outdoor local environmental information.

Another embodiment includes a method comprising installing an air sensor in an outflow duct of an HVAC system. The HVAC system further includes an inflow duct, an appliance, and a thermostat. The method further includes installing a current transformer on a conductor that extends between the appliance and the thermostat. The method also includes providing one or more processors. The one or more processors are configured to receive a set of measurements of a characteristic of outflowing air in the outflow duct. The set of measurements include a measurement of the characteristic associated with each time the current transformer detects the thermostat calling for the appliance to modify air flowing through the appliance. The one or more processors are further configured to establish a normal operation pattern based on the set of measurements. The one or more processors are further configured to receive a present measurement of the characteristic of outflowing air in the outflow duct from the air sensor. The present measurement is taken in connection with the current transformer detecting a present call for the appliance to modify air flowing through the appliance. The one or more processors are further configured to identify a deviation when the present measurement of the characteristic of outflowing air deviates from the normal operation pattern. The one or more processors are further configured to notify a user of the deviation.

The details of one or more examples of the disclosure are set forth in the accompanying drawings and the description below. Other features, objects, and advantages of the disclosure will be apparent from the description and drawings, and from the claims.

### BRIEF DESCRIPTION OF DRAWINGS

The following drawings are illustrative of particular examples of the present invention and therefore do not limit the scope of the invention. The drawings are not necessarily to scale, though embodiments can include the scale illustrated, and are intended for use in conjunction with the explanations in the following detailed description wherein like reference characters denote like elements. Examples of the present invention will hereinafter be described in conjunction with the appended drawings.

FIG. 1 is a conceptual diagram illustrating an example system for establishing a normal operation pattern for an appliance and monitoring the appliance for deviations, in accordance with some examples of this disclosure.

FIG. 2 is a block diagram illustrating a more detailed example of a computing device configured to perform the techniques described herein.

FIG. 3 is a flow diagram illustrating a method, in accordance with some examples of this disclosure.

### DETAILED DESCRIPTION

The following detailed description is exemplary in nature and is not intended to limit the scope, applicability, or configuration of the invention in any way. Rather, the following description provides some practical illustrations for implementing examples of the present invention. Those skilled in the art will recognize that many of the noted examples have a variety of suitable alternatives.

HVAC systems typically include an inflow duct that feeds air into an appliance, such as a furnace, an air conditioner, or a humidifier. The appliance will modify the air fed into the appliance and push the modified air into an interior environment. The modified air combines with the air in the interior environment in order to adjust a climate of the interior environment.

The appliance includes a number of parts that must work together in order to properly modify the air. For example, in a furnace, an induction motor turns on, a pressure switch flips to prove that furnace exhaust can be safely removed, a hot surface igniter warms up to prepare for ignition, a gas valve opens to cause ignition, a flame rectifier in the furnace circuit confirms that ignition has actually happened, and a blower motor starts, thereby causing heat transfer to begin. If any of those parts are wearing out or operating incorrectly, it may take longer to complete that step. For instance, if the gas valve does not open on the first or second try but opens on the third try, the heating process may be extended. Additionally, this may be a sign that the gas valve is wearing out.

Currently, most HVAC systems will not provide any easily interpreted information, to a layperson, that parts of the system are wearing out until the part actually breaks. In systems that do analyze the operation of the HVAC system, the system typically includes sensors both in an inflow duct and an outflow duct, where the measurements must be compared and plugged into certain equations before any evaluation of the data can be performed.

In general, the disclosure is directed to techniques for using measurements of a characteristic of air in the outflow duct, compared to a normal operation pattern, in order to determine whether the appliance is deviating from the normal operation pattern. Each time a thermostat calls for the appliance to adjust the local environment, the system may measure a characteristic of the air leaving the appliance through the outflow duct in order to establish a normal operation pattern. As the appliance continues to operate, the system can compare the updated measurements to the normal operation pattern to determine whether there has been a deviation by the appliance. If there has been a deviation, the system can notify a user or a repair service that repairs may be needed.

These techniques include numerous benefits. For instance, rather than requiring sensors in both an inflow duct and an outflow duct with additional operations to calculate differences between the inflow duct measurement and the outflow duct measurement, the techniques described herein may only take measurements in the outflow duct. By comparing the measurements in the outflow duct to a normal operation pattern, the overall calculations are simplified and decreased, improving the operation of the system performing these calculations. Additionally, by only taking measurements of the outflow duct, the installation is simplified. Trigger thresholds are more sensitive when based on one measurement rather than a combination of measurements, resulting in quicker determinations that measurements are to be taken. It is also easier to retrofit existing systems with sensors in a single location rather than in multiple locations.

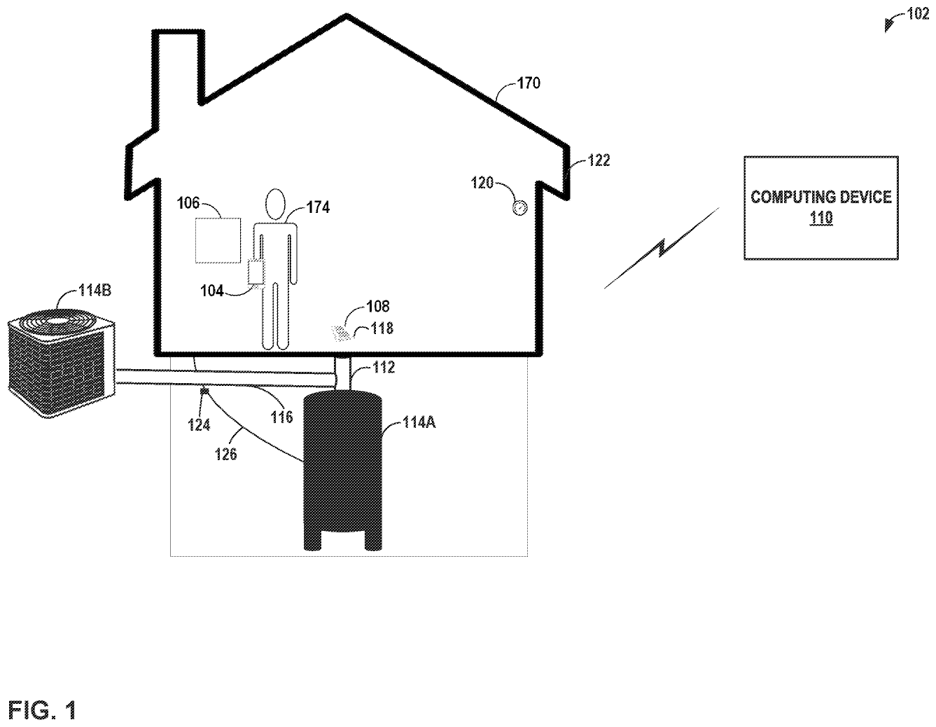

FIG. 1 is a conceptual diagram illustrating an example system 102 for establishing a normal operation pattern for appliance 114 and monitoring appliance 114 for deviations, in accordance with some examples of this disclosure. FIG. 1 includes building 170, which may be a home, an industrial building, or a commercial building. User 174 may utilize thermostat 106 to adjust a climate of building 170, either using thermostat 106 itself or mobile device 104.

Computing device 110 may be any computer, either local to building 170 or remote from building 170, with the processing power required to adequately execute the techniques described herein. For instance, computing device 110 may be any one or more of a mobile computing device (e.g., a smartphone, a tablet computer, a laptop computer, etc.), a desktop computer, a smarthome component (e.g., a computerized appliance, a home security system, a control panel for home components, a lighting system, a smart power outlet, etc.), a wearable computing device (e.g., a smart watch, computerized glasses, a heart monitor, a glucose monitor, smart headphones, etc.), a virtual reality/augmented reality/extended reality (VR/AR/XR) system, a video game or streaming system, a network modem, router, or server system, or any other computerized device that may be configured to perform the techniques described herein.

Appliances 114A and 114B (collectively, “appliance 114”) may be a part of an overall HVAC system of building 170 and may be any device capable of adjusting the climate of building 170. For instance, appliances 114 may be any one or more a furnace capable of heating air added to building 170 (e.g., appliance 114A), an air conditioner capable of cooling air added to building 170 (e.g., appliance 114B), or a humidifier/dehumidifier capable of adjusting the humidity of air added to building 170, among other things.

The HVAC system may further include inflow duct 116. Inflow duct 116 may take air, either from building 170 or from outside building 170, and feed the air into appliance 114 so that appliance 114 may modify one or more characteristics of the air.

The HVAC system may further include outflow duct 112. Outflow duct 112 may receive the modified air from appliance 114 and direct the modified air out of vent 108, attached to an end of outflow duct 112 opposite the end attached to appliance 114, and into the interior of building 170. In some examples, building 170 may include multiple instances of vent 108, potentially with each instance of vent 108 including a separate sensor 118 to take multiple measurements in accordance with the techniques described herein.

System 102 may further include sensor 118. Sensor 118 may be any sensor capable of measuring a characteristic of air travelling through outflow duct 112. For instance, sensor 118 may be any one or more of a temperature sensor, a pressure sensor, a humidity sensor, a particulate sensor, an acoustic sensor, and a gas sensor, among other things. In some instances, sensor 118 may be located near the end of outflow duct 112 that is connected to vent 108. In other instances, sensor 118 may be located near the end of outflow duct 112 that is connected to appliance 114. In general, sensor 118 may be located anywhere along the length of outflow duct 112, so long as the location remains static while the normal operation pattern is established and while additional measurements are taken in order to detect deviations such that the location of the sensor does not affect measurements taken for the particular characteristic.

In some instances, system 102 may further include environmental sensors, such as one or more of indoor environmental sensor 120 and outdoor environmental sensor 122. Environmental sensors 120 and 122 may be any sensors capable of measuring environmental information that may affect the air in outflow duct 112, such as a temperature sensor, a pressure sensor, a humidity sensor, a particulate sensor, an acoustic sensor, and a gas sensor, among other things. For instance, if inflow duct 116 takes air from outdoors to go into appliance 114, and the air outdoors is exceptionally cold, the air in outflow duct 112 may be colder than the normal operation pattern while no problem actually is occurring in appliance 114. As such, computing device 110 may take into account one or more of indoor local environmental information measured by indoor environmental sensor 120 and outdoor local environmental information measured by outdoor environmental sensor 122 when comparing measurements with normal operation patterns to determine whether system 102 is deviating from the normal operation pattern.

In accordance with the techniques described herein, system 102 provides an HVAC system that includes appliance 114, inflow duct 116, outflow duct 112, and thermostat 106. In some instances, the appliance may be any one or more of a furnace, an air conditioner, and a humidifier. System 102 may further provide air sensor 118 in outflow duct 112.

In some examples, thermostat 106 may receive an indication of user input to modify the air flowing through appliance 114. Thermostat 106 may then initiate a first call for appliance 114 to modify the air flowing through appliance 114. Thermostat 106 may also initiate the first call based on the sensed temperature in the space being outside of a previously specified range.

Sensor 118 may take a measurement of a characteristic of outflowing air in outflow duct 112 each time thermostat 106 calls for appliance 114 to modify air flowing through appliance 114. The characteristic may be any one or more of a temperature of the outflowing air in outflow duct 112, a blowing pressure of the outflowing air in outflow duct 112, a humidity of the outflowing air in outflow duct 112, a solid particle concentration of the outflowing air in outflow duct 112, a noise characteristic of the outflowing air in outflow duct 112, and a gas particle concentration of the outflowing air in outflow duct 112.

In some instances, in taking the measurement of the characteristic, sensor 118 may measure the characteristic of the outflowing air. Sensor 118 may then send the characteristic to computing device 110 that establishes the normal operation pattern.

Computing device 110 may establish a normal operation pattern based on the measurements, such as by creating a model based on one or more of the inputs provided to thermostat 106, how appliance 114 modifies air to get the climate inside building 170 to reach the inputs provided to thermostat, environmental factors, values of the measurements of the characteristic, an amount of time it takes for the air to reach the desired value, or any other number of statistics that may indicate health of the appliance.

Computing device 110 may then identify a deviation when a present measurement of the characteristic of outflowing air deviates from the normal operation pattern. For instance, computing device 110 may compare the present measurement of the characteristic to the normal operation pattern. Computing device 110 may determine whether the present measurement is greater than a threshold deviation away from the normal operation pattern. In response to determining that the present measurement is greater than the threshold deviation away from the normal operation pattern, computing device 110 may classify the present measurement as the deviation. The threshold may be any sufficiently deviated value, such as two or three standard deviations away from the determined “normal.”

Additionally, in response to determining that there is a deviation in the operation of appliance 114, computing device 110 may notify user 174 of the deviation, such as by pushing a notification to mobile device 104. In other instances, in response to identifying the deviation, computing device 110 may notify a remote server of the deviation.

Furthermore, computing device 110 may preserve additional appliance operation information for appliance 114 for a time period that includes when the present measurement was taken. For instance, system 102 may further provide one or more additional sensors in appliance 114. In response to thermostat 106 calling for appliance 114 to modify the air flowing through appliance 114, the one or more additional sensors may activate to measure the additional appliance operation information for at least the time period. The additional appliance operation information could include one or more of motor activation data (e.g., an indication of the motor activating or how quickly the motor activates), temperature control data (e.g., an internal temperature of appliance 114), gas valve data (e.g., how quickly a gas valve opens), rectifier confirmation data (e.g., confirmation that ignition has occurred), blower data (e.g., blower speed, blower pressure, how quickly the blower activates), and moisture data (e.g., internal moisture of appliance 114). Computing device 110 may further notify a remote server of the additional appliance operation information. The measurements may cease at an established time, such as a time the expected settings are expected to be met or a certain time after the expected settings are expected to be met.

In some instances, computing device 110 may account for both internal and external local environmental factors when determining the normal operation patterns and any deviations from said patterns. For instance, computing device 110 may determine local environmental factors, such as by receiving the factors from one or more of indoor local environmental sensor 120 or outdoor local environmental sensor 122. In such instances, in identifying the deviation, computing device 110 may identify the deviation based on the present measurement of the characteristic and the local environmental factors. The local environmental factors may include any one or more of indoor temperature, indoor humidity, outdoor temperature, outdoor humidity, and a local weather reading.

In one example of a use case of these techniques, thermostat 106 may call for appliance 114, which may be an air conditioner, to decrease the temperature in building 170. Sensor 118, which may be a temperature sensor, in outflow duct 112 measures how long it takes for the temperature of outflowing air in outflow duct 112 to decrease to the expected level (e.g., the temperature expected to cause the temperature in building 170 to reach the temperature input into thermostat 106). Sensor 118 sends the time measurement to computing device 110, which may be a local computer or a remote server. Computing device 110 compares the time measurement to a “normal” time measurement based on established normal operation patterns from previous measurements. If the time measurement is longer than “normal,” such as by a certain threshold, and potentially taking into account environmental factors, computing device 110 may alert a user that something may be wrong with appliance 114. In some instances, computing device 110 may further collect information about operation of appliance 114 and so that a technician can evaluate what may be wrong with appliance 114.

In another example of a use case of these techniques, thermostat 106 may call for appliance 114, which may be a furnace, to increase the temperature in building 170 (or in a given zone of building 170). Sensor 118 may begin sensing temperature when thermostat 106 calls for temperature increase (e.g., increasing the temperature in building 170 to 70 degrees Fahrenheit) and continues to sense the temperature until the outflow temperature reaches the expected level (e.g., 190 degrees Fahrenheit). The relatively small volume of air coming from the furnace may be at a high temperature in order to mix in with the relatively large volume of air in the space of building 170 and cause the overall air temperature in building 170 to rise. If the time measurement is longer than “normal,” such as by a certain threshold, and potentially taking into account environmental factors, computing device 110 may alert a user that something may be wrong with appliance 114. In some instances, computing device 110 may further collect information about operation of appliance 114 and so that a technician can evaluate what may be wrong with appliance 114.

The techniques described herein may not require full system replacements in order to execute properly. For instance, rather than setting up specific thermostats, sensors, and appliances that may communicate with one another and with computing device 110, an existing system may be retrofitted by installing sensor 118 in outflow duct 112 and installing a current transformer 124 on a conductor 126 that extends between thermostat 106 and appliance 114. The current transformer 124 may detect electric currents flowing from thermostat 106 to appliance 114, which may trigger sensor 118 to begin taking measurements as described herein. Current transformer 124 may also be situated on thermostat 106 to monitor a status of W1, W2, Y1, and/or Y2 nodes or wires on thermostat 106 to detect when an adjustment is being made.

For the purposes of this disclosure, a normal operation pattern may be an operation pattern established from a working appliance 114 after any sufficiently high number of measurements, as opposed to a technician's manual measurements or a pre-programmed value. Each environment may be unique, so it may be valuable to establish a normal operation pattern for each unique appliance and each unique environment to ensure accurate use information. The normal operation patterns may also take time of year or dates into account. Additionally, a different normal operation pattern may be established for each characteristic monitored by the system.

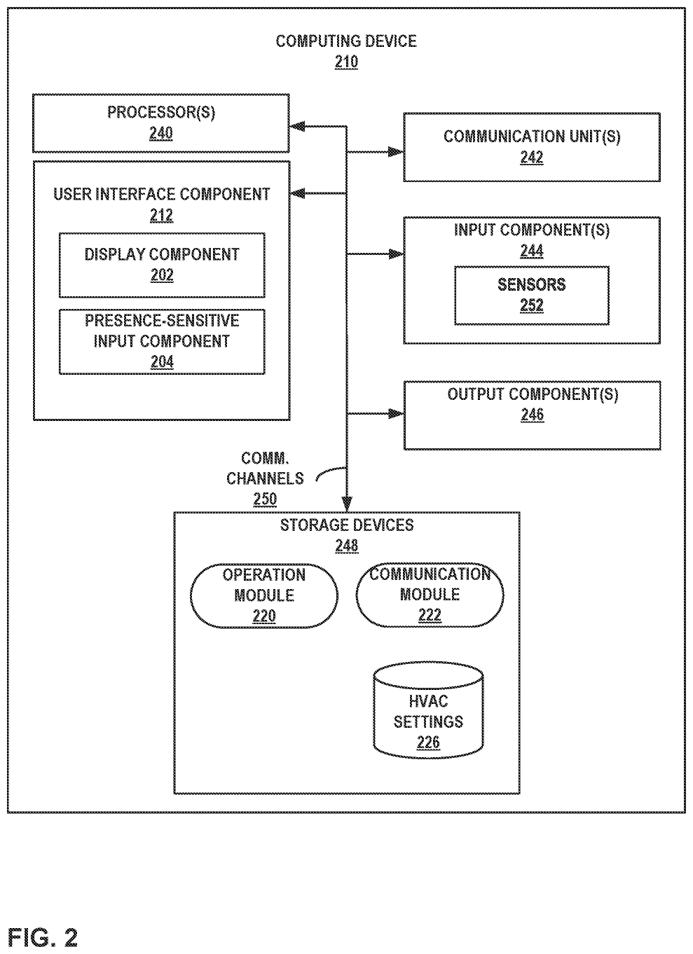

FIG. 2 is a block diagram illustrating an example computing device configured to determine a characteristic of received user input and output a corresponding set of sub-elements associated with an application on the computing device, in accordance with one or more aspects of the techniques described in this disclosure. Computing device 210 of FIG. 2 is described below as an example of computing device 110 of FIG. 1. FIG. 2 illustrates only one particular example of computing device 210, and many other examples of computing device 210 may be used in other instances and may include a subset of the components included in example computing device 210 or may include additional components not shown in FIG. 2.

Computing device 210 may be any computer with the processing power required to adequately execute the techniques described herein. For instance, computing device 210 may be any one or more of a mobile computing device (e.g., a smartphone, a tablet computer, a laptop computer, etc.), a desktop computer, a smarthome component (e.g., a computerized appliance, a home security system, a control panel for home components, a lighting system, a smart power outlet, etc.), a wearable computing device (e.g., a smart watch, computerized glasses, a heart monitor, a glucose monitor, smart headphones, etc.), a virtual reality/augmented reality/extended reality (VR/AR/XR) system, a video game or streaming system, a network modem, router, or server system, or any other computerized device that may be configured to perform the techniques described herein.

As shown in the example of FIG. 2, computing device 210 includes user interface component (UIC) 212, one or more processors 240, one or more communication units 242, one or more input components 244, one or more output components 246, and one or more storage components 248. UIC 212 includes display component 202 and presence-sensitive input component 204. Storage components 248 of computing device 210 include operation module 220, communication module 222, and HVAC settings data store 226.

One or more processors 240 may implement functionality and/or execute instructions associated with computing device 210 to receive initialization settings and transmit those initialization settings to a home automation device. That is, processors 240 may implement functionality and/or execute instructions associated with computing device 210 to establish normal operation patterns stored in HVAC settings data store 226 and determine deviations from said normal operation pattern.

Examples of processors 240 include application processors, display controllers, auxiliary processors, one or more sensor hubs, and any other hardware configure to function as a processor, a processing unit, or a processing device. Modules 220 and 222 may be operable by processors 240 to perform various actions, operations, or functions of computing device 210. For example, processors 240 of computing device 210 may retrieve and execute instructions stored by storage components 248 that cause processors 240 to perform the operations described with respect to modules 220 and 222. The instructions, when executed by processors 240, may cause computing device 210 to establish normal operation patterns stored in HVAC settings data store 226 and determine deviations from said normal operation pattern.

Operation module 220 may execute locally (e.g., at processors 240) to provide functions associated with managing and operating on data, for example, for establishing normal operation patterns and determining deviations of an appliance from said normal operation patterns. In some examples, operation module 220 may act as an interface to a remote service accessible to computing device 210. For example, operation module 220 may be an interface or application programming interface (API) to a remote server that establishes normal operation patterns and determines deviations of an appliance from said normal operation patterns.

In some examples, communication module 222 may execute locally (e.g., at processors 240) to provide functions associated with receiving information from sensors placed in an environment and outputting notifications to users or repair services. In some examples, communication module 222 may act as an interface to a remote service accessible to computing device 210. For example, communication module 222 may be an interface or application programming interface (API) to a remote server that coordinates the communication between computing device 210 and other devices.

One or more storage components 248 within computing device 210 may store information for processing during operation of computing device 210 (e.g., computing device 210 may store data accessed by modules 220 and 222 during execution at computing device 210). In some examples, storage component 248 is a temporary memory, meaning that a primary purpose of storage component 248 is not long-term storage. Storage components 248 on computing device 210 may be configured for short-term storage of information as volatile memory and therefore not retain stored contents if powered off. Examples of volatile memories include random access memories (RAM), dynamic random access memories (DRAM), static random access memories (SRAM), and other forms of volatile memories known in the art.

Storage components 248, in some examples, also include one or more computer-readable storage media. Storage components 248 in some examples include one or more non-transitory computer-readable storage mediums. Storage components 248 may be configured to store larger amounts of information than typically stored by volatile memory. Storage components 248 may further be configured for long-term storage of information as non-volatile memory space and retain information after power on/off cycles. Examples of non-volatile memories include magnetic hard discs, optical discs, floppy discs, flash memories, or forms of electrically programmable memories (EPROM) or electrically erasable and programmable (EEPROM) memories. Storage components 248 may store program instructions and/or information (e.g., data) associated with modules 220 and 222 and data store 226. Storage components 248 may include a memory configured to store data or other information associated with modules 220 and 222 and data store 226.

Communication channels 250 may interconnect each of the components 212, 240, 242, 244, 246, and 248 for inter-component communications (physically, communicatively, and/or operatively). In some examples, communication channels 250 may include a system bus, a network connection, an inter-process communication data structure, or any other method for communicating data.

One or more communication units 242 of computing device 210 may communicate with external devices via one or more wired and/or wireless networks by transmitting and/or receiving network signals on one or more networks. Examples of communication units 242 include a network interface card (e.g. such as an Ethernet card), an optical transceiver, a radio frequency transceiver, a GPS receiver, or any other type of device that can send and/or receive information. Other examples of communication units 242 may include short wave radios, cellular data radios, wireless network radios, as well as universal serial bus (USB) controllers.

One or more input components 244 of computing device 210 may receive input. Examples of input are tactile, audio, and video input. Input components 244 of computing device 210, in one example, includes a presence-sensitive input device (e.g., a touch sensitive screen, a PSD), mouse, keyboard, voice responsive system, camera, microphone or any other type of device for detecting input from a human or machine. In some examples, input components 244 may include one or more sensor components (e.g., sensors 252). Sensors 252 may include one or more biometric sensors (e.g., fingerprint sensors, retina scanners, vocal input sensors/microphones, facial recognition sensors, cameras) one or more location sensors (e.g., GPS components, Wi-Fi components, cellular components), one or more temperature sensors, one or more humidity sensors, one or more particulate sensors, one or more acoustic sensors, one or more gas sensors, one or more movement sensors (e.g., accelerometers, gyros), one or more pressure sensors (e.g., barometer), one or more ambient light sensors, and one or more other sensors (e.g., infrared proximity sensor, hygrometer sensor, and the like). Other sensors, to name a few other non-limiting examples, may include a heart rate sensor, magnetometer, glucose sensor, olfactory sensor, compass sensor, or a step counter sensor.

One or more output components 246 of computing device 210 may generate output in a selected modality. Examples of modalities may include a tactile notification, audible notification, visual notification, machine generated voice notification, or other modalities. Output components 246 of computing device 210, in one example, includes a presence-sensitive display, a sound card, a video graphics adapter card, a speaker, a cathode ray tube (CRT) monitor, a liquid crystal display (LCD), a light emitting diode (LED) display, an organic LED (OLED) display, a virtual/augmented/extended reality (VR/AR/XR) system, a three-dimensional display, or any other type of device for generating output to a human or machine in a selected modality.

UIC 212 of computing device 210 may include display component 202 and presence-sensitive input component 204. Display component 202 may be a screen, such as any of the displays or systems described with respect to output components 246, at which information (e.g., a visual indication) is displayed by UIC 212 while presence-sensitive input component 204 may detect an object at and/or near display component 202.

While illustrated as an internal component of computing device 210, UIC 212 may also represent an external component that shares a data path with computing device 210 for transmitting and/or receiving input and output. For instance, in one example, UIC 212 represents a built-in component of computing device 210 located within and physically connected to the external packaging of computing device 210 (e.g., a screen on a mobile phone). In another example, UIC 212 represents an external component of computing device 210 located outside and physically separated from the packaging or housing of computing device 210 (e.g., a monitor, a projector, etc. that shares a wired and/or wireless data path with computing device 210).

UIC 212 of computing device 210 may detect two-dimensional and/or three-dimensional gestures as input from a user of computing device 210. For instance, a sensor of UIC 212 may detect a user's movement (e.g., moving a hand, an arm, a pen, a stylus, a tactile object, etc.) within a threshold distance of the sensor of UIC 212. UIC 212 may determine a two or three-dimensional vector representation of the movement and correlate the vector representation to a gesture input (e.g., a hand-wave, a pinch, a clap, a pen stroke, etc.) that has multiple dimensions. In other words, UIC 212 can detect a multi-dimension gesture without requiring the user to gesture at or near a screen or surface at which UIC 212 outputs information for display. Instead, UIC 212 can detect a multi-dimensional gesture performed at or near a sensor which may or may not be located near the screen or surface at which UIC 212 outputs information for display.

In accordance with the techniques described herein, referencing FIG. 1 as if computing device 210 replaced computing device 110, system 102 provides an HVAC system that includes appliance 114, inflow duct 116, outflow duct 112, and thermostat 106. In some instances, the appliance may be any one or more of a furnace, an air conditioner, and a humidifier. System 102 may further provide air sensor 118 in outflow duct 112.

In some examples, thermostat 106 may receive an indication of user input to modify the air flowing through appliance 114. Thermostat 106 may then initiate a first call for appliance 114 to modify the air flowing through appliance 114.

Sensor 118 may take a measurement of a characteristic of outflowing air in outflow duct 112 each time thermostat 106 calls for appliance 114 to modify air flowing through appliance 114. The characteristic may be any one or more of a temperature of the outflowing air in outflow duct 112, a blowing pressure of the outflowing air in outflow duct 112, a humidity of the outflowing air in outflow duct 112, a solid particle concentration of the outflowing air in outflow duct 112, a noise characteristic of the outflowing air in outflow duct 112, and a gas particle concentration of the outflowing air in outflow duct 112.

In some instances, in taking the measurement of the characteristic, sensor 118 may measure the characteristic of the outflowing air. Sensor 118 may then send the characteristic to communication module 222 that establishes the normal operation pattern.

Operation module 220 may establish a normal operation pattern based on the measurements, such as by creating a model based on one or more of the inputs provided to thermostat 106, how appliance 114 modifies air to get the climate inside building 170 to reach the inputs provided to thermostat, environmental factors, values of the measurements of the characteristic, an amount of time it takes for the air to reach the desired value, or any other number of statistics that may indicate health of the appliance.

Operation module 220 may then identify a deviation when a present measurement of the characteristic of outflowing air deviates from the normal operation pattern. For instance, operation module 220 may compare the present measurement of the characteristic to the normal operation pattern. Operation module 220 may determine whether the present measurement is greater than a threshold deviation away from the normal operation pattern. In response to determining that the present measurement is greater than the threshold deviation away from the normal operation pattern, operation module 220 may classify the present measurement as the deviation.

Additionally, in response to operation module 220 determining that there is a deviation in the operation of appliance 114, communication module 222 may notify user 174 of the deviation, such as by pushing a notification to mobile device 104. In other instances, in response to identifying the deviation, communication module 222 may notify a remote server of the deviation.

Furthermore, operation module 220 may preserve additional appliance operation information for appliance 114 for a time period that includes when the present measurement was taken. For instance, system 102 may further provide one or more additional sensors in appliance 114. In response to thermostat 106 calling for appliance 114 to modify the air flowing through appliance 114, the one or more additional sensors may activate to measure the additional appliance operation information for at least the time period. The additional appliance operation information could include one or more of motor activation data (e.g., an indication of the motor activating or how quickly the motor activates), temperature control data (e.g., an internal temperature of appliance 114), gas valve data (e.g., how quickly a gas valve opens), rectifier confirmation data (e.g., confirmation that ignition has occurred), blower data (e.g., blower speed, blower pressure, how quickly the blower activates), and moisture data (e.g., internal moisture of appliance 114). Communication module 222 may receive the additional appliance operation information from the one or more additional sensors and notify a remote server of the additional appliance operation information.

In some instances, operation module 220 may account for both internal and external local environmental factors when determining the normal operation patterns and any deviations from said patterns. For instance, operation module 220 may determine local environmental factors, such as by communication module 222 receiving the factors from one or more of indoor local environmental sensor 120 or outdoor local environmental sensor 122. In such instances, in identifying the deviation, operation module 220 may identify the deviation based on the present measurement of the characteristic and the local environmental factors. The local environmental factors may include any one or more of indoor temperature, indoor humidity, outdoor temperature, outdoor humidity, and a local weather reading.

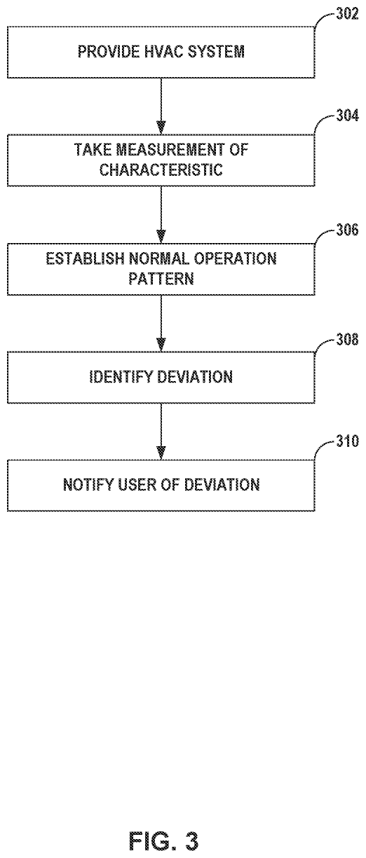

FIG. 3 is a flow diagram illustrating a method, in accordance with some examples of this disclosure. The techniques of FIG. 3 may be performed by one or more processors of a computing device, such as computing device 110 of FIG. 1 and/or computing device 210 illustrated in FIG. 2. For purposes of illustration only, the techniques of FIG. 3 are described within the context of computing device 210 of FIG. 2, although computing devices having configurations different than that of computing device 210 may perform the techniques of FIG. 3.

In accordance with the techniques described herein, an HVAC system may be provided, the HVAC system including an appliance, an inflow duct, an outflow duct, and a thermostat (302). A sensor takes a measurement of a characteristic of outflowing air in the outflow duct each time the thermostat calls for the appliance to modify air flowing through the appliance (304). Operation module 220 establishes a normal operation pattern based on the measurements (306). Operation module 220 further identifies a deviation when a present measurement of the characteristic of outflowing air deviates from the normal operation pattern (308). Communication module 222 notifies a user of the deviation (310).

It is to be recognized that depending on the example, certain acts or events of any of the techniques described herein can be performed in a different sequence, may be added, merged, or left out altogether (e.g., not all described acts or events are necessary for the practice of the techniques). Moreover, in certain examples, acts or events may be performed concurrently, e.g., through multi-threaded processing, interrupt processing, or multiple processors, rather than sequentially.

In one or more examples, the functions described may be implemented in hardware, software, firmware, or any combination thereof. If implemented in software, the functions may be stored on or transmitted over as one or more instructions or code on a computer-readable medium and executed by a hardware-based processing unit. Computer-readable media may include computer-readable storage media, which corresponds to a tangible medium such as data storage media, or communication media including any medium that facilitates transfer of a computer program from one place to another, e.g., according to a communication protocol. In this manner, computer-readable media generally may correspond to (1) tangible computer-readable storage media which is non-transitory or (2) a communication medium such as a signal or carrier wave. Data storage media may be any available media that can be accessed by one or more computers or one or more processors to retrieve instructions, code and/or data structures for implementation of the techniques described in this disclosure. A computer program product may include a computer-readable medium.

By way of example, and not limitation, such computer-readable storage media can comprise RAM, ROM, EEPROM, CD-ROM or other optical disk storage, magnetic disk storage, or other magnetic storage devices, flash memory, or any other medium that can be used to store desired program code in the form of instructions or data structures and that can be accessed by a computer. Also, any connection is properly termed a computer-readable medium. For example, if instructions are transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. It should be understood, however, that computer-readable storage media and data storage media do not include connections, carrier waves, signals, or other transitory media, but are instead directed to non-transitory, tangible storage media. Disk and disc, as used herein, includes compact disc (CD), laser disc, optical disc, digital versatile disc (DVD), floppy disk and Blu-ray disc, where disks usually reproduce data magnetically, while discs reproduce data optically with lasers. Combinations of the above should also be included within the scope of computer-readable media.

Instructions may be executed by one or more processors, such as one or more digital signal processors (DSPs), general purpose microprocessors, application specific integrated circuits (ASICs), field programmable logic arrays (FPGAs), or other equivalent integrated or discrete logic circuitry. Accordingly, the term “processor,” as used herein may refer to any of the foregoing structure or any other structure suitable for implementation of the techniques described herein. In addition, in some aspects, the functionality described herein may be provided within dedicated hardware and/or software modules configured for encoding and decoding, or incorporated in a combined codec. Also, the techniques could be fully implemented in one or more circuits or logic elements.

The techniques of this disclosure may be implemented in a wide variety of devices or apparatuses, including a wireless handset, an integrated circuit (IC) or a set of ICs (e.g., a chip set). Various components, modules, or units are described in this disclosure to emphasize functional aspects of devices configured to perform the disclosed techniques, but do not necessarily require realization by different hardware units. Rather, as described above, various units may be combined in a codec hardware unit or provided by a collection of interoperative hardware units, including one or more processors as described above, in conjunction with suitable software and/or firmware.

Various examples of the disclosure have been described. Any combination of the described systems, operations, or functions is contemplated. These and other examples are within the scope of the following claims.

What is claimed is:

1. A method comprising:
providing an HVAC system that includes an appliance, an inflow duct, an outflow duct, and a thermostat;
taking a measurement of a characteristic of outflowing air in the outflow duct each time the thermostat calls for the appliance to modify air flowing through the appliance;
establishing a normal operation pattern based on the measurements;
identifying a deviation when a present measurement of the characteristic of outflowing air deviates from the normal operation pattern; and
notifying a user of the deviation.

2. The method of claim 1, wherein identifying the deviation comprises:
comparing the present measurement of the characteristic to the normal operation pattern;
determining whether the present measurement is greater than a threshold deviation away from the normal operation pattern; and
in response to determining that the present measurement is greater than the threshold deviation away from the normal operation pattern, classifying the present measurement as the deviation.

3. The method of claim 1, further comprising:
receiving, by the thermostat, an indication of user input to modify the air flowing through the appliance; and
initiating, by the thermostat, a first call for the appliance to modify the air flowing through the appliance.

4. The method of claim 1, further comprising providing an air sensor in the outflow duct, wherein taking the measurement of the characteristic comprises:
measuring, by the air sensor, the characteristic of the outflowing air; and
sending, by the air sensor, the characteristic to one or more processors that establish the normal operation pattern.

5. The method of claim 4, wherein the air sensor comprises one or more of:
a temperature sensor,
a pressure sensor,
a humidity sensor,
a particulate sensor,
an acoustic sensor, and
a gas sensor.

6. The method of claim 1, wherein the characteristic comprises one or more of:
a temperature of the outflowing air in the outflow duct,
a blowing pressure of the outflowing air in the outflow duct,
a humidity of the outflowing air in the outflow duct,
a solid particle concentration of the outflowing air in the outflow duct,
a noise characteristic of the outflowing air in the outflow duct, and
a gas particle concentration of the outflowing air in the outflow duct.

7. The method of claim 1, further comprising:
in response to identifying the deviation, notifying a remote server of the deviation.

8. The method of claim 1, further comprising:
preserving additional appliance operation information for a time period that includes when the present measurement was taken.

9 The method of claim 8, further comprising:
providing one or more additional sensors in the appliance; and
in response to the thermostat calling for the appliance to modify the air flowing through the appliance, activating the one or more additional sensors to measure the additional appliance operation information for at least the time period.

10. The method of claim 8, wherein the additional appliance operation information comprises one or more of:
motor activation data,
temperature control data,
gas valve data,
rectifier confirmation data,
blower data, and
moisture data.

11. The method of claim 9, further comprising:
notifying a remote server of the additional appliance operation information.

12. The method of claim 1, wherein the appliance comprises one or more of:
a furnace,
an air conditioner, and
a humidifier.

13. The method of claim 1, further comprising:
determining a local environmental factor that comprises one or more of: indoor temperature, indoor humidity, outdoor temperature, outdoor humidity, and a local weather reading,
wherein identifying the deviation comprises identifying the deviation based on the present measurement of the characteristic and the local environmental factor.

14. A system comprising:
an HVAC system that includes an appliance, an inflow duct, an outflow duct, and a thermostat;
a first sensor provided in the outflow duct, the first sensor being configured to take a measurement of a characteristic of outflowing air in the outflow duct each time the thermostat calls for the appliance to modify air flowing through the appliance;
one or more processors configured to:
receive the measurements of the characteristic of the outflowing air in the outflow duct;
establish a normal operation pattern based on the measurements;
receive a present measurement of the characteristic of the outflowing air;
identify a deviation when the present measurement of the characteristic of outflowing air deviates from the normal operation pattern; and
in response to identifying the deviation, preserve additional appliance operation information for a time period that includes when the present measurement was taken.

15. The system of claim 14, further comprising a second sensor provided in the appliance, the second sensor being configured to, in response to the thermostat calling for the appliance to modify the air flowing through the appliance:
measure the additional appliance operation information for at least the time period, and
provide the additional appliance operation information to the one or more processors.

16. The system of claim 14, wherein the one or more processors is further configured to notify a user of the deviation.

17. The system of claim 14, wherein the one or more processors are further configured to:
notify a remote server of the additional appliance operation information.

18. The system of claim 14, wherein the system further comprises:
one or more indoor environmental sensors; and
one or more outdoor environmental sensors.

19. The system of claim 18, wherein the one or more processors are further configured to:
receive indoor local environmental information from the one or more indoor environmental sensors;
receive outdoor local environmental information from the one or more outdoor environmental sensors; and
identify the deviation based on the present measurement of the characteristic, the indoor local environmental information, and the outdoor local environmental information.

20. A method comprising:
installing an air sensor in an outflow duct of an HVAC system, the HVAC system further including an inflow duct, an appliance, and a thermostat;
installing a current transformer on a conductor that extends between the appliance and the thermostat;
providing one or more processors configured to:
receive a set of measurements of a characteristic of outflowing air in the outflow duct, the set of measurements including a measurement of the characteristic associated with each time the current transformer detects the thermostat calling for the appliance to modify air flowing through the appliance;
establish a normal operation pattern based on the set of measurements;
receive a present measurement of the characteristic of outflowing air in the outflow duct from the air sensor, the present measurement being taken in connection with the current transformer detecting a present call for the appliance to modify air flowing through the appliance;
identify a deviation when the present measurement of the characteristic of outflowing air deviates from the normal operation pattern; and
notify a user of the deviation.
